(19) United States
(12) Patent Application Publication
(10) Pub. No.: US 2016/0068429 A1
(43) Pub. Date: Mar. 10, 2016

(54) PATTERN FORMING METHOD, PHOTOMASK, AND TEMPLATE FOR NANOIMPRINT

(71) Applicant: KABUSHIKI KAISHA TOSHIBA, Tokyo (JP)

(72) Inventors: Masatoshi TERAYAMA, Kawasaki (JP); Machiko SUENAGA, Yokohama (JP); Takeharu MOTOKAWA, Zushi (JP); Hideaki SAKURAI, Kawasaki (JP)

(21) Appl. No.: 14/636,086

(22) Filed: Mar. 2, 2015

(30) Foreign Application Priority Data
Sep. 10, 2014 (JP) 2014-184412

(51) Int. Cl. C03C 15/00; G03F 1/80; C03C 17/38

(52) U.S. Cl. CPC C03C 15/00; C03C 17/38; G03F 1/80

(57) ABSTRACT

A pattern forming method includes forming a first region and a second region on a to-be-processed layer. The first region includes a guide pattern. In the second region, an affinity to one of the first segment and the second segment which are included in a self-assembly material, is higher than the affinity to the other. The self-assembly material is applied onto the first region and the second region. The self-assembly material is phase-separated into a first domain including the first segment, and a second domain including the second segment. Any one of the first domain and the second domain is selectively removed.

### CROSS-REFERENCE TO RELATED APPLICATION

This application is based upon and claims the benefit of priority from Japanese Patent Application No. 2014-184412, filed Sep. 10, 2014, the entire contents of which are incorporated herein by reference.

### FIELD

Embodiments described herein relate generally to a pattern forming method, a photomask, and a template for nanoimprint.

### BACKGROUND

Recently, as a fine patterning technology, practical use of directed self-assembly (DSA) techniques have attracted attention. Generally, in a pattern forming method using DSA techniques, an entire surface of a processed layer may be patterned. However, when a partial pattern on the layer is desired, it is difficult to confine the patterning to a specific region of the layer. Hence, when forming a desired pattern on a portion of a layer of a semiconductor device which may require leaving a portion of the layer un-patterned, an undesirable patterning is also performed in the region where no pattern is desired. Further, it is sometimes difficult to form a desired regular line and space pattern as a region of the pattern may exhibit non-linear features (i.e., a “fingerprint pattern”).

### DESCRIPTION OF THE DRAWINGS

FIG. 1A and FIG. 1B are a plan view and a cross-sectional view, respectively, illustrating a pattern forming method according to a first embodiment.

FIG. 2A and FIG. 2B are a plan view and a cross-sectional view, respectively, illustrating the pattern forming method according to the first embodiment.

FIG. 3A and FIG. 3B are a plan view and a cross-sectional view, respectively, illustrating the pattern forming method according to the first embodiment.

FIG. 4A and FIG. 4B are a plan view and a cross-sectional view, respectively, illustrating the pattern forming method according to the first embodiment.

FIG. 5A and FIG. 5B are a plan view and a cross-sectional view, respectively, illustrating the pattern forming method according to the first embodiment.

FIG. 6A and FIG. 6B are a plan view and a cross-sectional view, respectively, illustrating the pattern forming method according to the first embodiment.

FIG. 7A and FIG. 7B are a plan view and a cross-sectional view, respectively, illustrating the pattern forming method according to the first embodiment.

FIG. 8A and FIG. 8B are a plan view and a cross-sectional view, respectively, illustrating the pattern forming method according to the first embodiment.

FIG. 9 is a diagram showing an example of an undesired fingerprint pattern.

FIG. 10A and FIG. 10B are a plan view and a cross-sectional view, respectively, illustrating a pattern forming method according to a second embodiment.

### DETAILED DESCRIPTION

The exemplary embodiments provide a pattern forming method which may prevent formation of a fingerprint (random) pattern, and reduce the number of process steps, and a photomask and a template for nanoimprint processes which are manufactured using the pattern forming method.

In general, according to one embodiment, a pattern forming method comprises forming a first region and a second region on a to-be-processed layer. The first region includes a guide pattern. In the second region, an affinity to any one of a first segment and a second segment which are included in a self-assembly material, is greater than an affinity to the other. The self-assembly material is applied on the first region and the second region. The self-assembly material is phase-separated into a first domain including the first segment, and a second domain including the second segment. Any one of the first domain or the second domain is selectively removed to form a pattern.

Hereinafter, the embodiments will be described with reference to the drawings.

### First Embodiment

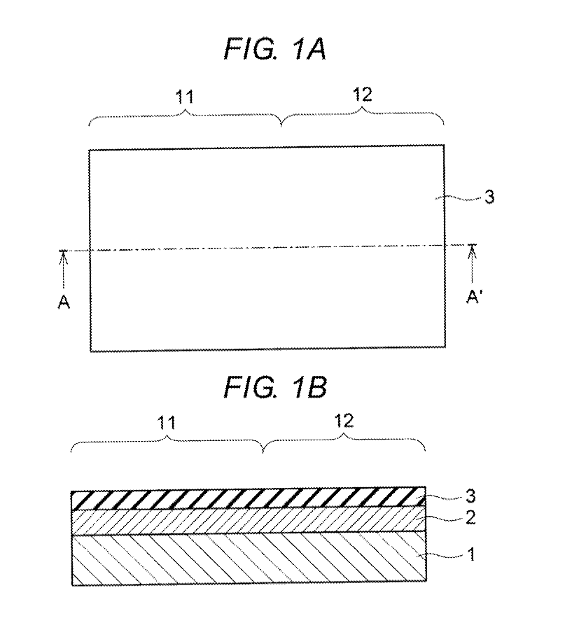

A pattern forming method according to a first embodiment, will be described with reference to FIG. 1A to FIG. 9. In the pattern forming method, a fine pattern is formed to a processing target, using a self-assembly material. For example, the self-assembly material is a block copolymer such as diblock copolymer or triblock copolymer, but is not limited thereto. The block copolymer is a copolymer in which a plurality of various types of polymers are chemically bonded. In the following description, each polymer configuring the block copolymer, is referred to as a segment.

The block copolymer includes a first segment having hydrophilic properties, and a second segment having hydrophobic properties. Here, the hydrophilic properties and the hydrophobic properties are relative properties. That is, the first segment is a segment of which the hydrophilic properties are higher among the segments configuring the block copolymer, and the second segment is a segment of which the hydrophobic properties are higher (i.e., the hydrophilic properties are lowest) among the segments configuring the block copolymer. Accordingly, in the first segment, the hydrophilic property is greater than that of the second segment, and in the second segment, the hydrophobic property is greater than that of the first segment (i.e., the second segment includes lower hydrophilic properties as compared to the first segment).

In the embodiment, for example, the block copolymer is PS-b-PMMA or PS-b-PDMS, but is not limited thereto. When the block copolymer is the PS-b-PMMA, the first segment is PMMA (polymethyl methacrylate), and the second segment is PS (polystyrene).

Here, FIG. 1A to FIG. 8B indicate the processing steps in each process of the pattern forming method. In FIG. 1A to FIG. 8B, “A” drawings are plan views, and “B” drawings are cross-sectional views taken along A-A′ lines of A drawings.

First, as shown in FIG. 1A and FIG. 1B, abase layer 2 is formed on a to-be-processed layer 1, and a neutralization film 3 is formed on the base layer 2.

The to-be-processed layer 1 is a processing target where a line and space pattern is to be formed using the pattern forming method. In FIG. 1A and FIG. 1B, the to-be-processed layer 1 is a quartz glass substrate, but is not limited thereto. For example, the to-be-processed layer 1 may be a semiconductor substrate or a glass substrate. Moreover, the to-be-processed layer 1 may be an arbitrary layer which is formed on a substrate.

The to-be-processed layer 1 includes a pattern region (first region) 11, and a non-pattern region (second region) 12. The pattern region 11 is a region where the line and space pattern may be formed in the to-be-processed layer 1, in the following process. Moreover, the non-pattern region 12 is a region where the line and space pattern is not to be formed on the to-be-processed layer 1, in the following process.

The base layer 2 is a hard mask for transferring a microphase-separation pattern (line and space pattern) of the block copolymer which is formed in the following process, on the to-be-processed layer 1. The base layer 2 is formed on both of the pattern region 11 and the non-pattern region 12, on the to-be-processed layer 1.

The base layer 2 is formed by an arbitrary material which has an etching rate that is similar to an etch rate of the to-be-processed layer 1, and has an affinity with respect to any one of the first segment and the second segment of the block copolymer. Here, the affinity is a relative property. That is, the base layer 2 having an affinity to the first segment means that the affinity to the first segment of the base layer 2, is greater than the affinity to the second segment. Similarly, when the base layer 2 has an affinity to the second segment, this means that the affinity to the second segment of the base layer 2, is greater than the affinity to the first segment.

In FIG. 1A and FIG. 1B, the base layer 2 includes a metal such as Cr, but is not limited thereto. For example, the metal which is included in the base layer 2, may be Si, Mo, or Ta. The base layer 2 is formed by layering such material on the to-be-processed layer 1 by a sputtering method, or the like.

The neutralization film 3 is utilized as a guide pattern when the block copolymer is microphase-separated in the following process. The neutralization film 3 is formed on both of the pattern region 11 and the non-pattern region 12, on the base layer 2.

The neutralization film 3 is a thin film which is neutral with respect to the first segment and the second segment of the block copolymer. Here, the term of neutral means that the neutralization film 3 has an equivalent affinity with the first segment and the second segment. For example, the neutralization film 3 may be formed by a mixture of a portion of the first segment and substance portion of the second segment, or a random copolymer of the first segment and the second segment.

Specifically, when the block copolymer is the PS-b-PMMA, the mixture of the PS and the PMMA, or PS-r-PMMA which is the random copolymer of the PS and the PMMA, is dissolved in PGMEA (polyethylene glycol monomethyl ether acetate) at a concentration of 1.0 wt %. The resultant mixture is spin coated at a rotation rate of 2000 rpm, is baked for 90 seconds at 110° C. on a hot plate, and thereafter, is baked for 3 minutes at 240° C., and thereby, the neutralization film 3 may be formed.

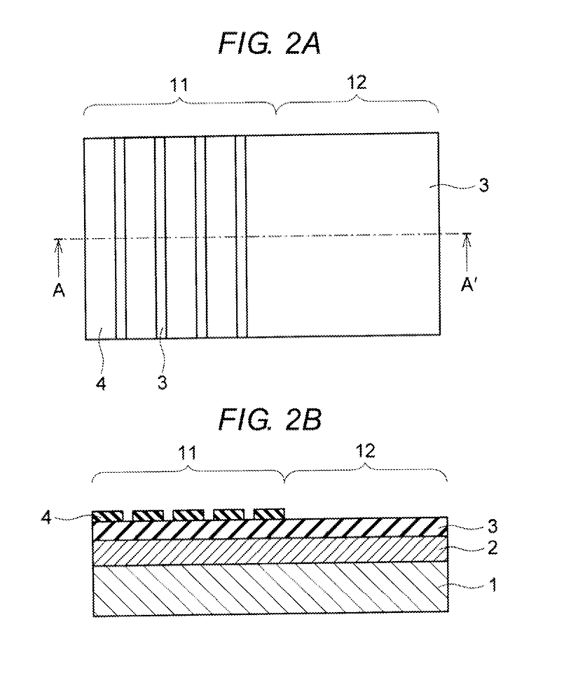

Next, as shown in FIG. 2A and FIG. 2B, on the neutralization film 3, a line and space pattern shaped resist pattern 4 is formed. The resist pattern 4 is formed by spin coating a resist material onto an entire surface of the neutralization film 3, and removing a portion of the resist material by exposure and development. For example, a thickness of the applied resist material is 100 nm. Additionally, for example, the exposure is performed by an ArF excimer laser, at an exposure amount of 20 mJ/cm².

In more detail, in the resist material which is applied onto the pattern region 11 on the neutralization film 3, a pattern of the above line and space pattern shape is formed. Hereby, the resist pattern 4 is formed in the pattern region 11. The neutralization film 3 is exposed within the spaces or opening in the pattern region 11.

In contrast thereto, the resist material which is applied onto the non-pattern region 12 on the neutralization film 3, is completely removed. In the non-pattern region 12, the entire surface of the neutralization film 3 is thus exposed.

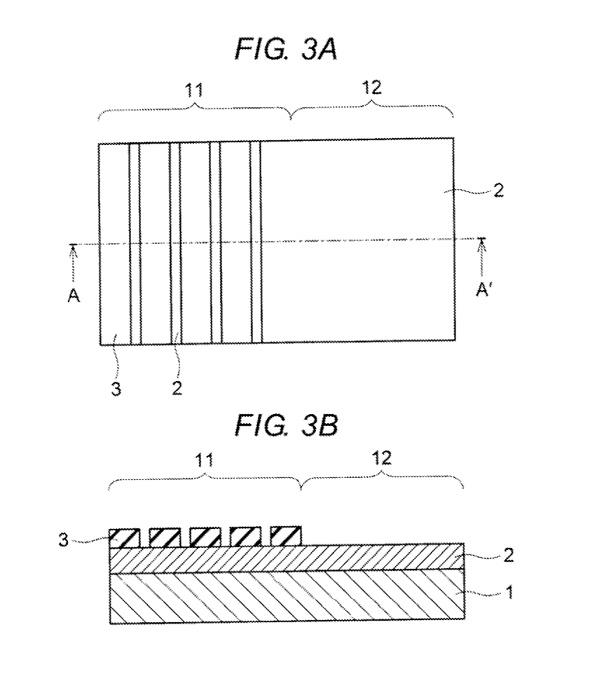

Next, as shown in FIG. 3A and FIG. 3B, by using the resist pattern 4 as a mask, the neutralization film 3 is etched. For example, the processing of the neutralization film 3 is performed by dry etching using oxygen. Therefore, after etching the neutralization film 3, the resist pattern 4 is removed. For example, the resist pattern 4 may be removed by using a thinner or resist specific solvent, or the like.

Hereby, the resist pattern 4 is transferred to the pattern region 11, and a line and space pattern shaped guide pattern is formed thereon. The guide pattern consists of the base layer 2 (space portion) which is exposed from the portion where the neutralization film 3 is removed, and the neutralization film 3 which remains forms the line portion. The guide pattern is a guide for forming a regular ordering of the first segment and the second segment at the time of microphase-separating the block copolymer in the following process. In the guide pattern, the base layer 2 functions as a chemical guide, and the neutralization film 3 functions as a physical guide.

Moreover, by the etching, the neutralization film 3 of the non-pattern region 12 is completely removed. Hereby, in the non-pattern region 12, the entire surface of the base layer 2 is exposed. Consequently, the non-pattern region 12 is a region which has an affinity with respect to only one of the first segment and the second segment.

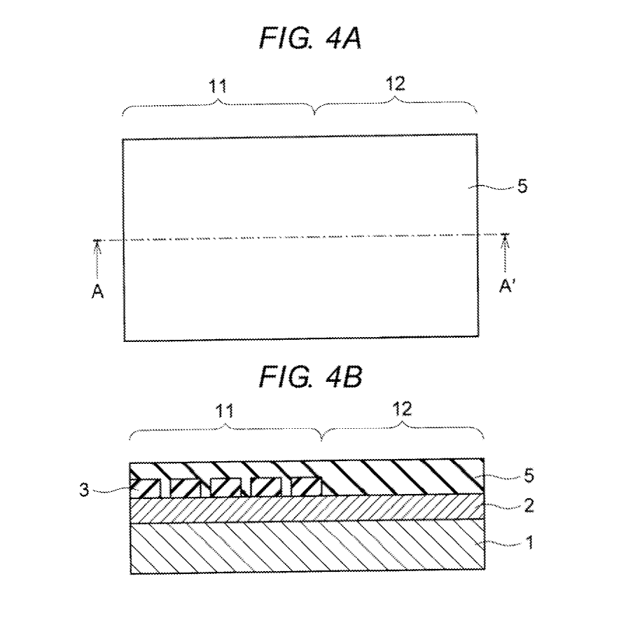

Next, as shown in FIG. 4A and FIG. 4B, a block copolymer layer 5 is formed, by spin coating the block copolymer including the first segment and the second segment, onto the base layer 2 and the neutralization film 3. The block copolymer is PS-b-PMMA, and the PS-b-PMMA is dissolved in the PGMEA so as to be at a concentration of approximately 1.0 wt %, and is spin coated at a substrate rotation rate of 2000 rpm. For example, the thickness from the base layer 2 of the block copolymer layer 5 is 35 nm.

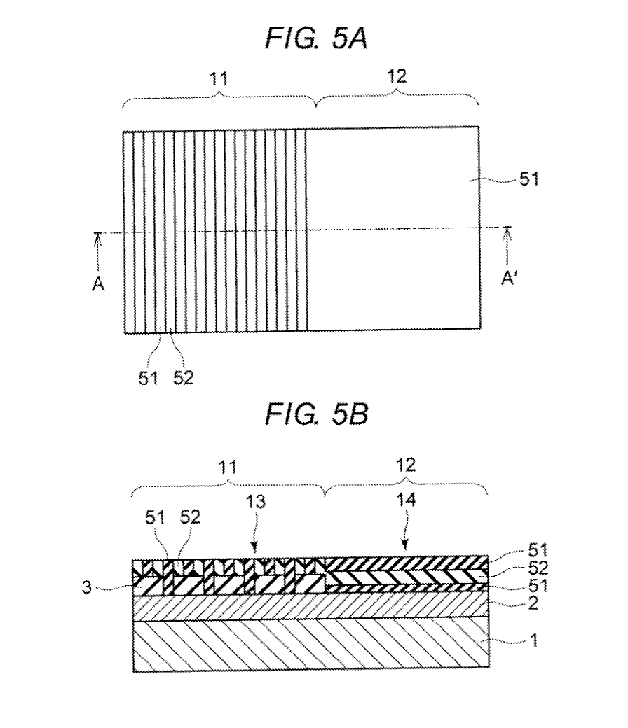

Next, as shown in FIG. 5A and FIG. 5B, the block copolymer layer 5 is annealed. Hereby, the block copolymer layer 5 is microphase-separated into a first domain 51 including the first segment and a second domain 52 including the second segment, and the microphase-separation pattern is formed.

By the annealing processing, in the pattern region 11, a microphase-separation pattern 13 of a lamellar structure where the first domain 51 and the second domain 52 are alternately arranged in a linear direction along the base layer in the spaces and along the guide layer therebetween, is formed. In the pattern region 11, the guide pattern including the base layer 2 and the neutralization film 3 is formed, and the block copolymer is microphase-separated according to the guide pattern, and for this reason, the microphase-separation pattern 13 is formed.

For example, when the base layer 2 has an affinity to the first segment, the first segment is attached to the portion where the base layer 2 is exposed, that is, to the space portion of the guide pattern, and the first domain 51 is formed. Therefore, on the neutralization film 3, that is, in the line portion of the guide pattern, by using the first domain 51 which is formed in the space portion as a starting point, the first segment and the second segment are alternately formed.

Hereby, as shown in FIG. 5A and FIG. 5B, the lamellar structure in which the first domain 51 and second domain 52 are alternately arranged, and extend generally parallel to one another in the linear direction on the to be processed layer 1 (and also in an orientation that is perpendicular, i.e., also extend upwardly from, the to-be-processed layer 1), is formed. In the case where the base layer 2 has an affinity to the second segment, in the pattern region 11, the microphase-separation pattern of the lamellar structure in which positions of the first domain 51 and the second domain 52 are switched in comparison with FIG. 5A and FIG. 5B, will be formed.

Since the microphase-separation pattern 13 is formed on and between portions of the guide pattern, the microphase-separation pattern 13 is formed into the line and space pattern shape which is parallel to the length direction of the spaces in the guide pattern. Moreover, as described above, since a plurality of patterns are formed on the neutralization film 3 of the guide pattern, the microphase-separation pattern 13 is formed into the line and space pattern shape which is finer than the guide pattern. In the following process, the microphase-separation pattern 13 is transferred to the to-be-processed layer 1.

Furthermore, dimensions of the space portion and the line portion of the guide pattern may be arbitrary dimensions which are capable of guiding the microphase-separation of the block copolymer layer 5.

In contrast thereto, in the non-patterned region 12, a microphase-separation pattern 14 of the lamellar structure in which the first domain 51 and the second domain 52 are alternately arranged in a height direction, i.e., as a layer of one over the other and each layer generally parallel to the base layer 2 surface, is formed. In the non-pattern region 12, the base layer 2 is exposed on the entire surface, and for this reason, the microphase-separation pattern 14 is formed.

For example, when the base layer 2 has an affinity to the first segment, as described above, the first segment is formed where the base layer 2 is exposed. Since the base layer 2 is exposed along the entire surface of the non-pattern region 12, the first segment is formed on the entire exposed surface of the base layer 2 in non-patterned region 12. Thereby, on the base layer 2, the layer of the first domain 51 which is parallel to the base layer 2, is formed. Therefore, by using the first domain 51 as a starting point, the first segment and the second segment are alternately arranged in parallel, stacked layers one over the other as shown in FIG. 5B.

Hereby, as shown in FIG. 5B, the microphase-separation pattern 14 of the lamellar structure in which the layer of the first domain 51 and the layer of the second domain 52 are alternately layered in the height direction, is formed. In the case where the base layer 2 has an affinity to the second segment in the non-pattern region 12, the microphase-separation pattern of the lamellar structure in which the positions of the first domain 51 and the second domain 52 are switched in comparison with FIG. 5A and FIG. 5B, is formed.

For example, when the block copolymer is the PS-b-PMMA, the PS-b-PMMA is annealed for 3 minutes at 220° C. under nitrogen atmosphere. As a result, the PS-b-PMMA is microphase-separated, and the microphase-separation patterns 13 and 14 are formed as described above. That is, in the pattern region 11, the line and space pattern shaped microphase-separation pattern 13 including the PMMA domain (first domain 51) of a half pitch of approximately 15 nm and the PS domain (second domain 52), is formed. Moreover, in the non-pattern region 12, the layer of the PMMA domain having a thickness of approximately 5 nm is formed on the base layer 2, and the layer of the PS domain having a thickness of approximately 15 nm and the layer of the PMMA domain are formed thereon.

Furthermore, the number of layers of the first domain 51 and the layers of the second domain 52 which are formed in the non-pattern region 12, is arbitrary, and varies according to a film thickness of the block copolymer layer 5 or lengths of the first domain 51 and the second domain 52 of the block copolymer.

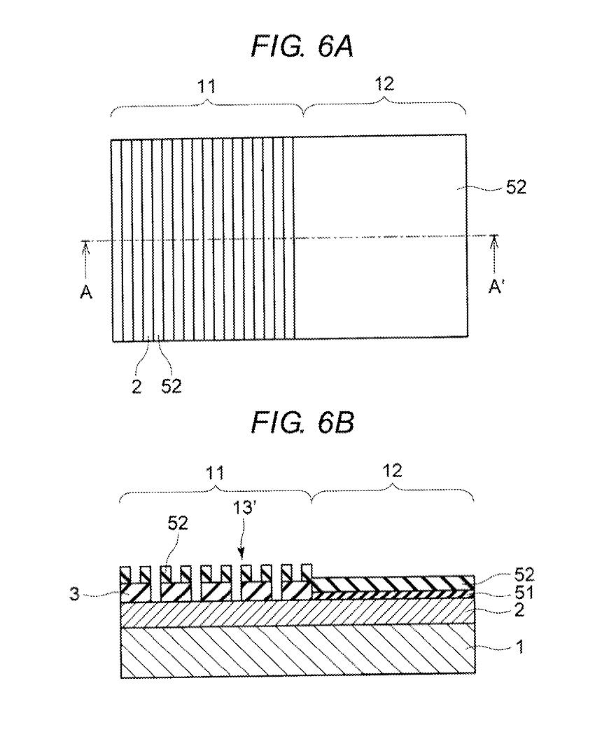

Next, as shown in FIG. 6A and FIG. 6B, the first domain 51 is selectively removed by the etching. Hereby, in the pattern region 11, a line and space pattern (microphase-separation pattern 13′) using the second domain 52 as a line portion is formed. Additionally, in the non-pattern region 12, the layer of the second domain 52 is exposed.

For example, when the block copolymer is the PS-b-PMMA, by the dry etching using nitrogen, it is possible to selectively remove the PMMA (first domain 51).

Furthermore, depending on the affinity of the base layer 2 with respect to the first domain or the second domain, the second domain 52 may be selectively removed, instead of the first domain 51. In this case, in the pattern region 11, a line and space pattern using the first domain 51 as a line portion is formed. Moreover, in the non-pattern region 12, the layer of the first domain 51 is exposed.

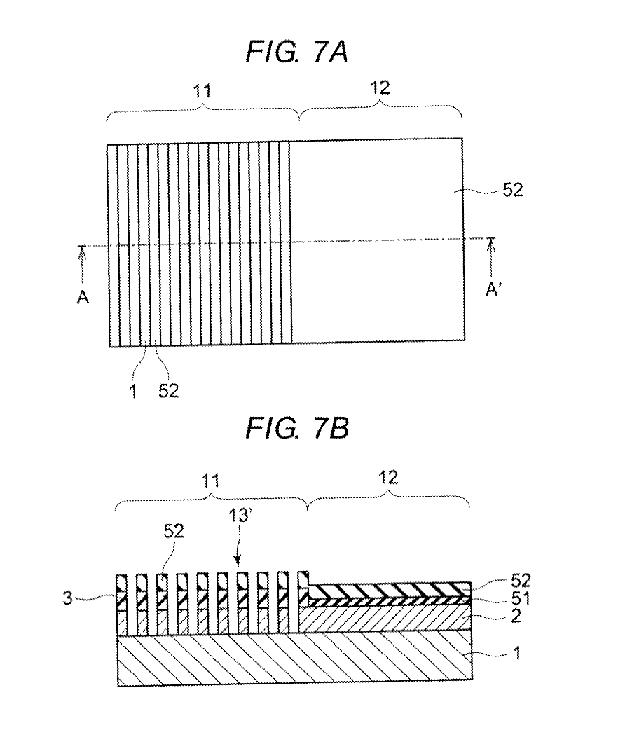

Next, as shown in FIG. 7A and FIG. 7B, the base layer 2 is etched using the second domain 52 as a mask. As a result, the microphase-separation pattern 13 is transferred to the base layer 2 in the pattern region 11. Since the entire surface is masked by the second domain 52, the non-pattern region 12 of the base layer 2 is not etched.

For example, when the block copolymer is the PS-b-PMMA, by the dry etching using a chlorine-based gas, it is possible to etch the base layer 2. Hereby, in the pattern region 11 of the base layer 2, the line and space pattern of the half pitch of approximate 15 nm, is formed.

Furthermore, in the previous process, if the second domain 52 is selectively removed instead of the first domain 51, the base layer 2 may be etched by using the first domain 51 as a mask. Hereby, in the pattern region 11 of the base layer 2, the line and space pattern in which the line portion and the space portion of FIG. 7B are switched, is formed.

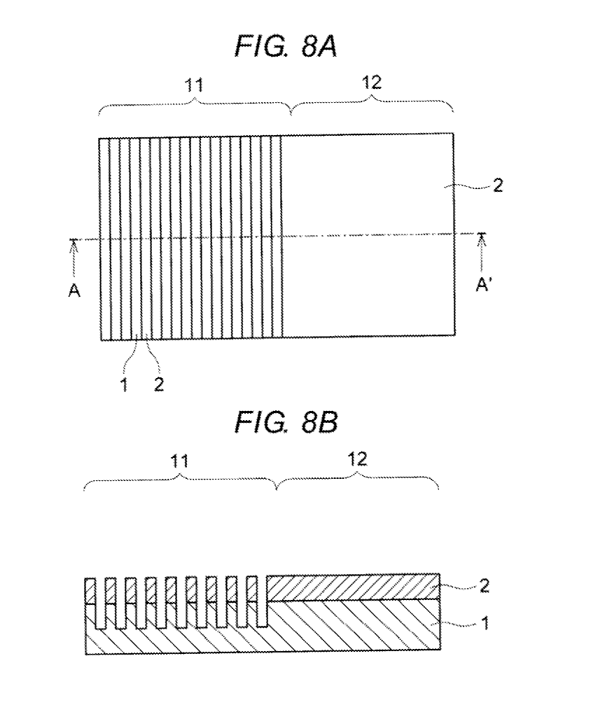

Next, as shown in FIG. 8A and FIG. 8B, the neutralization film 3, the first domain 51, and the second domain 52 which remain on the base layer 2, are removed, and the to-be-processed layer 1 is etched by using the now fully patterned base layer 2 as a mask. In the pattern region 11, the line and space pattern of the base layer 2 is transferred to the to-be-processed layer 1, and the line and space pattern is formed. Since the entire surface is masked by the base layer 2, and the non-pattern region 12 of the to-be-processed layer 1 is not etched. For example, when the to-be-processed layer 1 is a quartz glass substrate, it is possible to remove portions of the to-be-processed layer 1 by dry etching using a fluorine-based gas to transfer the pattern in the pattern region 11 to the to be processed layer 1.

Furthermore, the etching of the to-be-processed layer 1 may be performed in a state where the patterned neutralization film 3, the first domain 51, and the second domain 52 remain on the base layer 2 in the pattern region, and the neutralization film 3, the first domain 51, and the second domain 52 in the non-patterned region 12. In this case, it is possible to reduce the number of processes, because the neutralization film 3, the first domain 51, and the second domain 52 can be stripped from the substrate after the to be processed layer 1 is patterned.

As described above, according to the pattern forming method according to the embodiment, the base layer 2 which has an affinity to any one of the first segment and the second segment, is exposed. Hereby, in the non-pattern region 12, any one of the first domain 51 and the second domain 52 is formed as a starting point, and a layered structure including a layer of the first domain 51 and a layer of the second domain 52 is formed on the base layer 2. Consequently, when any one of the first domain 51 or the second domain 52 is removed, the non-pattern region 12 is masked by the remaining first domain 51 or second domain 52 and hence protected from being etched.

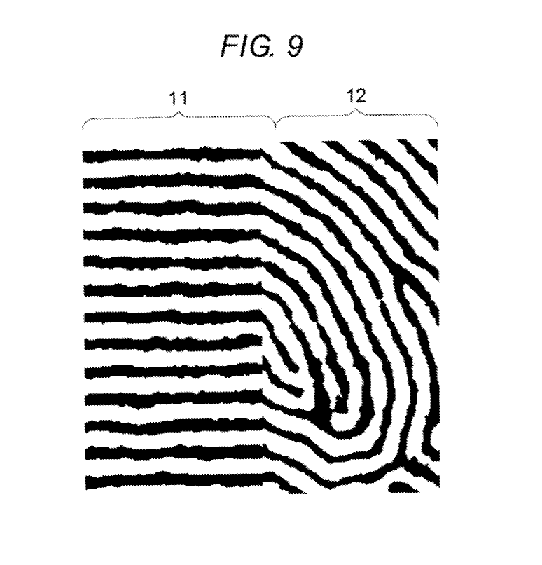

Hence, due to the ordered horizontal layering of the first segment and the second segment in the non-pattern region 12, a fingerprint pattern as shown in FIG. 9 which forms when the of the first segment and the second segment are formed on a surface without the presence of a guide layer, is not formed, and a process to remove the fingerprint pattern or a process of forming a protection film in order to protect the base layer 2 in the non-patterned region 12 at the time of etching the patterned region, is not necessary. Thus, it is possible to reduce the number of processes for pattern formation. If a fingerprint pattern is formed, it may a short circuit of wiring, the process of removing the fingerprint pattern and/or the process of forming a protection film in order to protect the base layer 2 at the time of etching, is necessary.

Furthermore, the pattern forming method may be applied to the patterning of a quartz glass substrate, or the like. Accordingly, using the pattern forming method, it is possible to manufacture a photomask and a template for nanoimprint. By using the pattern forming method, it is possible to reduce manufacturing processes of the photomask and the template for nanoimprint, and it is possible to form a fine pattern.

### Second Embodiment

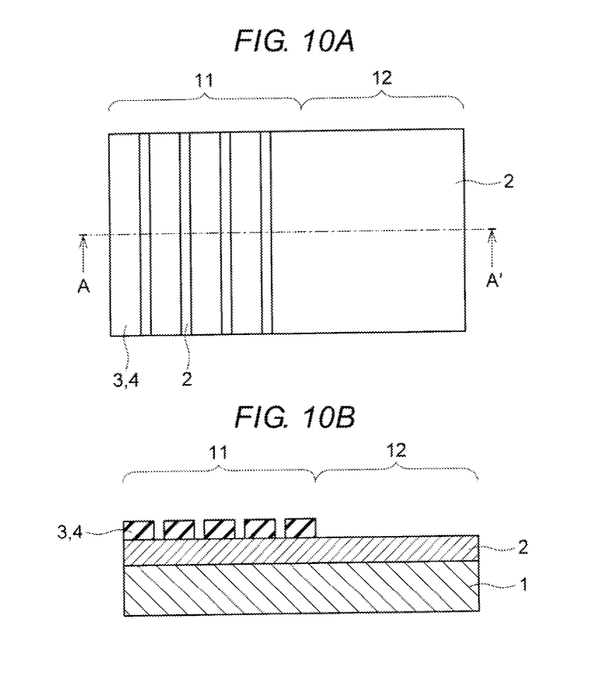

A pattern forming method according to a second embodiment, will be described with reference to FIG. 10A and FIG. 10B. In the pattern forming method according to the embodiment, as a resist material, a material, which is neutral with respect to the first segment and the second segment of the block copolymer, is used.

First, as shown in FIG. 10A and FIG. 10B, the base layer 2 is formed on the to-be-processed layer 1, a line and space pattern shaped resist pattern 4 is formed in the pattern region 11 on the base layer 2. The resist pattern 4 is formed by spin coating the resist material onto the base layer 2, and removing portions of the resist material by the exposure and the development.

The formed resist pattern 4 is neutral with respect to the block copolymer, and therefore, serves a function as the neutralization film 3 in the first embodiment. That is, in this embodiment, the neutralization film 3 is formed by the resist material.

After forming the resist pattern 4, the block copolymer layer 5 is formed on the base layer 2 and the resist pattern 4. The subsequent processes are the same as those of the first embodiment.

As described above, according to the pattern forming method relating to the embodiment, it is possible to form the neutralization film 3 with the resist material. Consequently, the process of forming and etching the neutralization film 3, or the process of removing the resist pattern 4 after etching the neutralization film 3 in the first embodiment, is not necessary, and it is possible to further reduce the number of processes for the pattern formation.

Furthermore, it is possible to form the resist pattern 4 in the first embodiment, by the resist material which is neutral with respect to the block copolymer. In this case, since the process such as the process of removing the resist pattern 4 after etching the neutralization film 3 is not necessary, it is possible to reduce the number of processes for the pattern formation.

Moreover, the embodiments are not limited to the above embodiments, and may be realized by modifying configuration components within the scope without departing from the gist thereof in execution stages. Additionally, various kinds of embodiments may be formed by appropriately combining a plurality of configuration components which are disclosed in each of the above embodiments. For example, the configuration in which several configuration components are removed from all configuration components which are indicated in each embodiment, may be considered. Furthermore, the configuration components which are described in different embodiments, may be appropriately combined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern forming method comprising:
forming, on a to-be-processed layer, a first region that includes a guide pattern, and a second region having a greater affinity to one of a first segment or a second segment which are included in a self-assembly material;
applying the self-assembly material onto the first region and the second region;
phase-separating the self-assembly material into a first domain including the first segment, and a second domain including the second segment; and
selectively removing any one of the first domain and the second domain.

2. The method according to claim 1,
wherein the forming of the second region includes
forming a base layer having a greater affinity to one of the first segment and the second segment on the to-be-processed layer;
forming a neutralization film which is neutral with respect to the first segment and the second segment on the base layer; and
exposing the base layer, by removing the neutralization film.

3. The method according to claim 2, further comprising:
selectively removing any one of the first domain and the second domain;
etching the neutralization film and the base layer, by using the remaining first domain or the second domain as a mask; and
etching the to-be-processed layer, by using the base layer as a mask.

4. The method according to claim 2,
wherein the self-assembly material is a block copolymer.

5. The method according to claim 2,
wherein the base layer includes at least one of Si, Mo, Cr, and Ta.

6. The method according to claim 2,
wherein the to-be-processed layer is a quartz glass substrate.

7. The method according to claim 2,
wherein the neutralization film includes a resist material.

8. The method according to claim 2, further comprising:
forming a first pattern where the first domain and the second domain are alternately layered on the second region, by phase-separating the self-assembly material.

9. The method according to claim 1,
wherein the forming of the first region includes
forming a base layer having a greater affinity to one of the first segment and the second segment on the to-be-processed layer;
forming a neutralization film which is neutral with respect to the first segment and the second segment on the base layer; and
forming the guide pattern including the neutralization film and the base layer, by removing the neutralization film in a predetermined pattern.

10. The method according to claim 9, further comprising:
selectively removing any one of the first domain and the second domain;
etching the neutralization film and the base layer, by using the remaining first domain or the second domain as a mask; and
etching the to-be-processed layer, by using the base layer as a mask.

11. The method according to claim 9,
wherein the self-assembly material is a block copolymer.

12. The method according to claim 9,
wherein the base layer includes at least one of Si, Mo, Cr, and Ta.

13. The method according to claim 9,
wherein the to-be-processed layer is a quartz glass substrate.

14. The method according to claim 9,
wherein the neutralization film includes a resist material.

15. The method according to claim 1, further comprising:
forming a first pattern where the first domain and the second domain are alternately layered on the second region, by phase-separating the self-assembly material.

16. The method according to claim 1, further comprising:
selectively removing any one of the first domain and the second domain;
etching the neutralization film and the base layer, by using the remaining first domain or the second domain as a mask; and
etching the to-be-processed layer, by using the base layer as a mask.

17. A pattern forming method comprising:
forming, on a quartz glass substrate, a first region that includes a guide pattern, and a second region having a greater affinity to one of a first segment or a second segment which are included in a self-assembly material;
applying the self-assembly material onto the first region and the second region;
phase-separating the self-assembly material into a first domain including the first segment, and a second domain including the second segment; and
selectively removing any one of the first domain and the second domain.

18. The method according to claim 17,
wherein the forming of the second region includes
forming a base layer having a greater affinity to one of the first segment and the second segment on the to-be-processed layer;
forming a neutralization film which is neutral with respect to the first segment and the second segment on the base layer; and
exposing the base layer, by removing the neutralization film.

19. A pattern forming method comprising:
forming, on a quartz glass substrate, a first region that includes a guide pattern, and a second region having a greater affinity to one of a first polymer chain or a second polymer chain which are included in a self-assembly material;
applying the self-assembly material onto the first region and the second region;
phase-separating the self-assembly material into a first domain including the first segment, and a second domain including the second segment; and
selectively removing any one of the first domain and the second domain, wherein the first domain comprises a linear line pattern oriented perpendicular to the to-be-processed layer, and the second region comprises a linear line pattern oriented parallel to the to-be-processed layer.

20. The method according to claim 19,
wherein the forming of the second region includes
forming a base layer having a greater affinity to one of the first segment and the second segment on the to-be-processed layer;
forming a neutralization film which is neutral with respect to the first segment and the second segment on the base layer; and
exposing the base layer, by removing the neutralization film.
